(19) United States
(12) Patent Application Publication
(10) Pub. No.: US 2017/0320726 A1
(43) Pub. Date: Nov. 9, 2017

(54) MEMS Package

(71) Applicant: AT & S Austria Technologie & Systemtechnik Aktiengesellschaft, Leoben (AT)

(72) Inventors: Markus Leitgeb, Trofaiach (AT); Nick Renaud-Bezot, Leoben (AT)

(21) Appl. No.: 15/525,875

(22) PCT Filed: Nov. 10, 2015
(86) PCT No.: PCT/EP2015/076158

§ 371 Date: May 10, 2017

(30) Foreign Application Priority Data
Nov. 10, 2014 (EP) 14290341.8

(51) Int. Cl. B81C 1/00; B81B 7/00; H04R 19/04; H04R 19/00; H04R 19/02

(52) U.S. Cl. CPC B81C 1/0023; H04R 19/005; H04R 19/02; H04R 19/04; B81B 7/0061; B81B 2201/0257; B81B 2207/012; B81B 2207/095; H04R 2201/003; B81C 2203/0785

(57) ABSTRACT

A package includes a base structure, which has an electrically isolating material and/or an electrically conductive contact structure, an electronic component, which is embedded in the base structure or is arranged on the base structure, a microelectromechanical system (MEMS) component, and a cover structure, which is mounted on the base structure for at least partially covering the MEMS component.

### CROSS-REFERENCE TO RELATED APPLICATIONS

The present application is a national phase application emerged from international patent application PCT/EP2015/076158, which claims the benefit of the filing date of European Patent Application No. 14 903 341.8, filed on Nov. 10, 2014, the disclosures of which are hereby incorporated herein by reference in their entirety.

### TECHNICAL FIELD

The invention relates to a package, an assembly and a method for manufacturing an electronic device.

### TECHNOLOGICAL BACKGROUND

MEMS (microelectromechanical systems) components were initially manufactured with conventional semiconductor tools. Specific requirements in respect of, for example, dimensions, materials, shapes, etc., have led to the development of special processes. These further developments with respect to the origins have led to the controller ICs not being manufactured on the same substrates as the MEMS components themselves. Even though CMOS-compatible processes have been introduced (which enabled single-chip MEMS/ICs), the large plurality of MEMS applications separates the sensor/actuator from the control unit. With the progressing trend to smaller shape factors and improved performance at lower costs, there exists room for further developments in respect of heterogeneous integration.

### SUMMARY

There may be a need to provide a package that can be manufactured efficiently.

According to an embodiment example of the present invention, there is established a package (i.e. an encased electronic module), which comprises a base structure, which has an electrically isolating material and/or an electrically conductive contact structure; an electronic component, which is embedded in the base structure or is arranged on the base structure; a microelectromechanical system (MEMS) component (which can be mounted, for example, on the base structure); and a cover structure, which is mounted on the base structure for at least partially covering the MEMS component.

According to a further embodiment example of the present invention, there is established a method for manufacturing packages, wherein in the method an electronic component is embedded in a base structure or the electronic component is arranged on the base structure, which has an electrically isolating material and/or an electrically conductive contact structure; a microelectromechanical system (MEMS) component is mounted (in particular at the base structure, alternatively or in addition to the cover structure mentioned hereinafter); and the MEMS component is covered at least partially with a cover structure, which is mounted to the base structure.

According to a further embodiment example of the present invention, there is established an assembly (in particular a pre-form of a package having the features described above), wherein the assembly comprises: a base master structure, which has an electrically isolating material and/or an electrically conductive contact structure; a plurality of electronic components, which are embedded in the base master structure and/or are arranged on the base master structure; a plurality of MEMS components (in particular at the base master structure, alternatively or additionally at the cover master structure mentioned hereinafter); and a cover master structure, which is mounted at the base master structure and at least partially covers the MEMS components, in order to thus define individual cavities for each one of the MEMS components between a respective section of the base master structure and a respective section of the cover master structure.

In the context of the present application, the expression “electronic component” may be understood to refer to any active electronic component (such as, for example, an electronic chip, in particular a semiconductor chip) or any arbitrary passive electronic component (such as, for example, a capacitor). Examples of the embedded components and/or assemblies may be a data storage, such as, for example, a DRAM (or any other arbitrary storage), a filter (which may be configured, for example, as a high pass filter, a low pass filter or a bandpass filter, and which may serve, for example, for filtering frequencies), an integrated circuit (for example, a logic IC), a signal processing component (such as, for example, a microprocessor), a power management component, an opto-electric interface element (for example, an opto-electronic component), a voltage converter (such as, for example, a DC/DC converter or an AC/DC converter), a cryptographic component, a capacity, an inductivity, a switch (for example a transistor-based switch), and a combination of these and other functional electronic components.

By the provision of the base structure from a dielectric material having electrically conductive contacting structures formed thereon and/or therein it may be possible to confer to the underlayment (or basis) of the at least one electronic component and the at least one MEMS component simultaneously a mechanical attachment function and an electrical contacting function. Such an architecture may be compatible, in particular, with the usage of a PCB substrate or a portion thereof as a base structure, which may enable a cost-efficient manufacture and the fallback to well-defined PCB processes and thus to make accessible the PCB technology for the MEMS technology. Alternatively however, completely electrically conductive base structures, such as for example a leadframe, may also be used. By an embedding or integrating of the at least one electronic component in the base structure, a low construction height of the package may be achieved, even if the electronic component and the MEMS component are arranged one on top of the other. Alternatively however, non-embedded architectures may also be possible. By enabling a vertical arrangement of the electronic component and the MEMS component by the burying of the electronic component in the base structure, a low lateral extension of the package may be achievable, too. Furthermore, by the electrically isolating material of the base structure, a dielectrical mounting base can be provided, and by the provision of an electrically conductive contact structure in and/or on this electrically conductive material a contacting between the buried electronic component and the MEMS component can be accomplished. Such an arrangement may also be flexible in respect of the usage of a cover structure, which may be formed in totally different configurations and which may shield the MEMS component towards the environment. At the same time, the package may be protected mechanically and sealed to the outside by a mounting of the cover structure at the base structure. In summary, there may be provided a package, which may be compact and easily manufacturable, and which may in particular be manufacturable also in a batch-type architecture. To this end, a plurality of electronic components may be embedded in a base master structure or set thereon, and correspondingly a plurality of MEMS components may be mounted on the base master structure. After covering the thus obtained arrangement by a cover master structure, a pre-form for a plurality of packages may be obtained. By a mere singularizing of this arrangement, a plurality of packages can be attained. In addition to the achievable small footprint, the embedding of the at least one electronic component may have the further advantages of a better electronic performance and a lower energy consumption as a result of the shorter conductive paths between the at least one electronic component and the at least one MEMS component.

In the following, additional exemplary embodiment examples of the package, the assembly and the method are described.

According to an exemplary embodiment example, the MEMS component may be mounted at the base structure. Alternatively or in addition, the MEMS component may be mounted at the cover structure. The MEMS component may also be embedded at least partially in the base structure and/or in the cover structure.

In an according manner, the MEMS components may be mounted at the base master structure. Alternatively or in addition, the MEMS components may be mounted at the cover master structure. The MEMS components may also be embedded at least partially in the base master structure and/or in the cover master structure.

According to an exemplary embodiment example, the base structure may be configured as a conductor board, in particular as a printed circuit board, or as a section or as a portion of such a conductor board. By providing the base plate as a conductor board, in particular as a printed circuit board (PCB), a mounting base may be provided for the MEMS component and the electronic component, which [mounting base] can be manufactured cost-efficiently and wherein the mature PCB technology can be put to application. Also, by the provision of the electrically isolating material and an electrically conductive contact structure, a mechanical mounting and an electrical contacting may be enabled for conductor boards at the same time. However, it is to be noted that the expression “conductor board” may comprise other architectures, such as for example a ceramic substrate or other substrates.

According to an exemplary embodiment example, the cover structure may be a casting compound and/or a metal cap and/or further electrically isolating material, optionally combined with a further electrically conductive contacting structure (in particular a conductor board, further in particular a printed circuit board, or a section or a portion of such a conductor board). According to a first embodiment, the cover structure may have a casting compound (for example a mould compound or an optically transparent casting compound), which may encapsulate the MEMS structure in particular with leaving open the mechanically movable structure of the MEMS component. Alternatively, a metal cap may be superimposed, which provides for a particular robust mechanical shielding of the MEMS component. According to a particularly preferred embodiment example, it may also be possible to form the cover structure (in particular in connection with a base structure which may be realized as a printed circuit board) as a conductor board (which may comprise a plurality of mutually connected layer structures of electrically conductive material and electrically isolating material, and which may in particular be plate-shaped and/or flat) and further preferably as a printed circuit board (PCB). By this configuration, it may be possible to enable a configuration (or structural shape), which may be compact in the height direction, by two plate-type components as the base structure and the cover structure with low manufacturing cost and low manufacturing effort. At the same time, this architecture may enable a batch-wise manufacture of a plurality of packages. Cavities for receiving the MEMS structure and/or the at least one electronic component may be established in the cover structure, which is embodied as a printed circuit board, for example, by means of mechanical abrasion (for example drilling), levelling or cutting (for example by means of a laser) or chemically (for example by means of etching).

According to an exemplary embodiment example, the electrically isolating material may be selected from a group, which consists of resin (in particular bismaleimide-triazine resin), glass fibres, prepreg material, polyimide, a liquid crystal polymer, epoxy-based build-up films, and FR4 material. Resin material may serve as a mechanically stable matrix, which at the same time confers to the respective structure electrically isolating properties. The provision of glass fibres may strengthen the electrically isolating material mechanically and may also cause a desired spatial anisotropy of the mechanical properties. Prepreg material may be a pre-form of FR4 material, and may comprise a mixture of resin and glass fibres. By the usage of according prepreg films having openings, a basis may be established for receiving the electronic components in the openings (or grouting [the components] directly in the material) and after grouting of the thus obtained structure with further prepreg films, the electronic components may be embedded to the full extent in the electrically isolating material. FR4 (flame resistant) refers to a common material for conductor boards, which may enable a high mechanical robustness at low cost for an MEMS package according to the invention.

According to an exemplary embodiment example, the electronic component may be configured for functionally cooperating with, in particular for controlling, the MEMS component. To this end, the electronic component and the MEMS component may be coupled electrically with one another, which may be effected by means of the electrically conductive contacting. Electrical signals may then be communicated between the electronic assembly and the MEMS component. According to an embodiment, the electronic component may transmit electronic control signals to the MEMS component, on the basis of which the latter may provide a function (in particular an actuator function). Reversely, also the MEMS component may generate an electrical signal (for example a sensor signal, if the MEMS component is embodied as a sensor) and may provide this to the electronic component for further processing.

According to an exemplary embodiment example, the MEMS component may be configured as one of the group consisting of: a sensor and an actuator.

According to a first embodiment, the MEMS component may also be an actuator. An actuator may be understood to be an MEMS component, which may effect a mechanical movement in reaction to a stimulus signal. Such an actuator may, for example, be a loudspeaker (in particular a balanced armature receiver), which, upon application of an electrical signal, may excite a piezoelectric membrane to [perform] vibrations and to emit acoustical waves. Other examples of actuators as MEMS components may be a micropump or a haptic actuator, which may allow a haptic feedback upon applying an electrical signal, for example in order to confirm a user input to an electronic device. An MEMS actuator may also be a scanner, an autofocus component, an adjustable lens or an adaptable wavelength-selective filter. An adjustable wavelength-selective filter is an MEMS component, which may change its capacity in a characteristic manner upon application of an electrical voltage, so as to be transmissive or reflective thereby especially for a particular wavelength of electromagnetic radiation, such as for example light.

Alternatively, the MEMS component may be embodied as a sensor, which may output a sensor signal that is characteristical for a property of the environment on the basis of this property of the environment. A microphone may be an example for this, which may generate an electrical signal in reaction to sound waves or acoustical waves which may be present in the environment, for example by means of a piezoelectric membrane. Other examples of MEMS sensors may be a pressure sensor or a fluid sensor (wherein a fluid may comprise a gas and/or a liquid or may consist thereof).

According to an exemplary embodiment example, the electronic component may be a semiconductor chip, in particular an application specific integrated circuit chip (ASIC). By the formation of the at least one electronic component of the package as a semiconductor chip, the advantages of the integrated circuit technology can be applied, in particular the provision of electronic functions in a miniaturized manner. It may also be possible to program an electronic chip using an ASIC, such that a user-defined electronic function is ensured. According to an embodiment example, also a plurality of electronic components may be provided in a single package, wherein the electronic components may be arranged on and/or in the base structure.

However, the at least one electronic component may also be embodied in another manner as a controller chip, for example as a CCD (charge coupled device). In this embodiment example, the electronic component may detect electromagnetic radiation, in particular it may sense image data. In such an embodiment example, the electronic component of the CCD type may, for example, be embedded in the base structure (wherein an upper surface of the CCD assembly shall be exposed in respect of the base structure, in order to possibly be receptive for electromagnetic radiation) and may cooperate operatively (or functionally) with an adjustable lens of the MEMS type, which may be arranged above the electronic component of the CCD type, in order to thus possibly serve as an adaptable optical element for influencing the electromagnetic radiation that is detected by means of the CCD.

According to an exemplary embodiment example, at least a portion of lateral surfaces (or surfaces at the side) of the electronic component may be covered with material of the base structure. According to this embodiment, the side surfaces of the at least one electronic component may be covered totally or partially with electrically isolating material and/or with electrically conductive material of the base structure. The electronic component may either be integrated completely in the base structure, or may project at the upper side and/or at the lower side from the base structure. By such an integration, a compact constructional shape of the package can be achieved.

According to an exemplary embodiment example, at least one of the group, which may consist of the base structure and the cover structure, may have at least one via hole for providing a fluid connection (in particular an air connection or a liquid connection) between the MEMS component and an environment of the package. By the provision of one or plural via holes, an operative connection of the MEMS component with the environment may be enabled (in particular a sensoric and/or actuatoric operative connection). For example, in the case of an embodiment of the MEMS component as a loudspeaker or a microphone, an acoustic connection can be provided through the via hole to the environment, in particular in order to possibly output sound waves from the MEMS component into the environment or to detect sound waves from the environment by means of the MEMS component. When realizing the MEMS component as a sensor, another property of the environment (for example the presence of a fluid, a particular pressure, etc.) can be transmitted through the via hole onto the sensor component, too.

According to an exemplary embodiment example, at least one of the group, which may consist of the base structure and the cover structure, may have a surface structuring for influencing acoustic waves, and may in particular be chamfered. The chamfering or other surface structuring of the base structure and/or of the cover structure, in particular in the area of the via hole, may allow to set, in particular, the acoustical properties in this area, for example for filtering particular frequencies, suppressing noise, defining propagation paths of sound waves, etc. Also the guiding of sound waves, etc. along such surface grooves or levellings may thus be possible. By a chamfering around a via hole, sharp edges at the via hole can be smoothed and a funnel (or cone) shaped access for acoustic waves can be established, whereby the acoustical properties of the package may be fostered.

According to an exemplary embodiment example, the MEMS component can be localized in a cavity, in particular in a rectangular-shaped or a hemisphere-shaped cavity, which can be confined between the base structure and the cover structure. By accommodating the MEMS component in a cavity, in which it may be in a direct air connection to the environment at least along a portion of its surface, the MEMS component can fulfil its function, which may comprise a mechanical movement. By a cap (or canopy) type provision of the cover structure, such a cavity can be formed cost-efficiently.

According to an exemplary embodiment example, the cover structure may have a feature for adjusting (or setting) an acoustic property, in particular a functionalization or a structuring for passively filtering acoustical waves. By the functionalization (for example surface coating) and/or the structuring (for example forming surface recesses, such as for example notches), the acoustical properties of the package can be adjusted and undesired effects, such as for example noise or the coupling in of undesired acoustical frequencies, can be suppressed or totally avoided. Generally, the feature for adjusting an acoustical property may be an arrangement of one or a plurality of microstructures, i.e. micro-protrusions (for example solder balls) and/or micro-cavities (such as for example indentations), which may be arranged at an inner surface and/or at an outer surface of the cover structure, in order to possibly influence the properties, according to which acoustic waves propagate in an environment of the cover structure. It may also be possible to provide solder pads and/or ESD (electrostatic discharge) protection devices and/or EMI (electromagnetic interference) projection devices.

According to an exemplary embodiment example, the package may have bond material and/or connection material at a mounting site between the base structure and the cover structure. Such a bond material may for example be an adhesive, by which the cover structure can be attached mechanically to the base structure. Such a bond material may for example be solder or a conductive paste, by means of which the cover structure can be electrically coupled to the base structure. Also, a batch-wise formation of packages can thus be facilitated with simple means.

According to an exemplary embodiment example, at least a portion of the electrically conductive contact structure can be configured for electrically coupling the electronic component to the MEMS component. The electrically conductive contact structure of the base structure (and/or optionally an according electrically conducting contact structure of the cover structure) may thus be used directly or indirectly (for example, by interposition of a bond wire) for electrically contacting the electronic component and the MEMS component. Thus, the base structure and/or the cover structure may not only serve for mechanically attaching and shielding of the electronic component and the MEMS component, but simultaneously also for electrically contacting. According to an embodiment, the electronic chip controls the MEMS component, such that electrical control signals, which may influence the function of the MEMS component, can be transmitted from the electronic chip to the MEMS component. For example, a corresponding electrical signal can be applied to an MEMS component that may be implemented as a loudspeaker, which signal may then be converted, by the MEMS component, to according sound waves. According to another embodiment, the electronic component may (pre-)process electrical signals, which may have been generated by the MEMS component, and may thus generate for example a sensor output. The connection between the base structure and the cover structure can be formed, for example, by means of soldering or mechanically grouting (or pressing together), preferably with the use of bond material therebetween.

In a particular preferred embodiment example, the bond material may be configured to provide both a mechanical connection and also an electrical coupling between the base structure and the cover structure. In such an embodiment example, the bond material may itself be electrically conductive and may bridge a small gap between an electrically conductive contact structure of the base structure and an electrically conducting contact structure of the cover structure.

According to an exemplary embodiment example, in the method, at least one further electronic component can be embedded in a base master structure, or the at least one further electronic component can be arranged on a base master structure, wherein the base structure may form a portion of the base master structure; at least one further MEMS component can be mounted to the base master structure; at least the one further MEMS component can be covered at least partially with a cover master structure, which may be mounted at the base master structure, wherein the cover structure may form a portion of the cover master structure. According to this embodiment, the whole processing of the manufacturing of plural packages (for example simultaneously of at least 10, in particular at least 100 packages) can be effected by the usage of large-area base master structures and/or cover master structures. Both the base master structure and also the cover master structure can each represent, for example, a conductor board (in particular a printed circuit board). By the embedding or surface mounting of electronic components and the mounting of MEMS components being effected batch-wise, by covering the thus obtained, populated base master structure with one single cover master structure, and by a singularizing (for example by sawing, etching or laser cutting) taking place only subsequently, an efficient manufacture of the package may be possible. These advantages may become possible in particular when using printed circuit boards as the basis for the base master structure and/or the cover master structure, because then only two plane (or two-dimensional) components must be attached to one another. When using a printed circuit board as a basis for the cover master structure, a simple mechanical, for example by a laser, or a chemical structuring of the structured conductor board from a processing side may be sufficient to form the cavities for distance-afflicted receiving of the MEMS components.

According to an exemplary embodiment example, furthermore, a singularizing of the arrangement of the base master structure with the electronic components and the mounted MEMS components and the cover master structure, which may be attached to one another by means of bond material, can be effected, so as to thus possibly obtain at least two (in particular a large plurality) of packages, of which each one may have: a base structure, at least one electronic component, at least one MEMS component, and a cover structure. By the singularization and/or separation only after the group-wise processing of many electronic assemblies and MEMS components, the manufacturing cost can be reduced.

According to an exemplary embodiment example, the electronic components and the MEMS components may be distributed two-dimensionally across the base master structure and the cover master structure. In particular, the electronic components or MEMS components can be attached along rows and columns on a plate-shaped base master structure. The singularization can thus also be effected along rows and columns.

### BRIEF DESCRIPTION DRAWINGS

Exemplary embodiment examples of the present invention are described hereinafter with reference to the following figures.

FIG. 1 shows a cross-sectional view of a package according to an exemplary embodiment example of the invention.

FIG. 2 shows a cross-sectional view of a package according to another exemplary embodiment example of the invention.

FIG. 3 shows a cross-sectional view of a package according to still another exemplary embodiment example of the invention.

FIG. 4 shows another view of the package according to FIG. 3.

FIG. 5 shows a cover master structure according to an exemplary embodiment example of the invention.

FIG. 6 shows a base master structure according to an exemplary embodiment example of the invention.

FIG. 7 shows a schematic view for illustrating individual processes during a method for manufacturing packages according to an exemplary embodiment example of the invention.

FIG. 8 shows a base master structure according to another exemplary embodiment example of the invention.

FIG. 9 shows a schematic view for illustrating individual processes according to a method for manufacturing packages according to another exemplary embodiment example of the invention.

FIG. 10 shows a cover master structure according to another exemplary embodiment example of the invention.

FIG. 11 shows a cross-sectional view of an assembly according to another exemplary embodiment example of the invention.

FIG. 12 shows a cross-sectional view of a package according to another exemplary embodiment example of the invention.

FIG. 13 and FIG. 14 show cross-sectional views of packages according to other exemplary embodiment examples of the invention.

### DETAILED DESCRIPTION OF EXEMPLARY EMBODIMENTS

Same or similar components in different figures are provided with same reference numerals.

Before exemplary embodiment examples of the invention are described with reference to the figures, some general aspects of the invention shall still be explained:

According to an exemplary embodiment example, a PCB-based packaging architecture for MEMS components (in particular MEMS sensors or MEMS actuators) may be provided.

According to an exemplary embodiment example of the invention, one semiconductor chip or plural semiconductor chips, or other electronic components, may be arranged on a substrate (which is also referred to as base master structure) in a format of stripes (or streaks, bands). Thereby, mechanisms such as die attach, flipchipping (i.e. a back side arrangement of electronic chips on the substrate), wirebonding (i.e. the provision of bond wires for contacting electronic chips) can be applied, in order to possibly accomplish desired electrical and mechanical connections. A second stripe (which may also be referred to as cover master structure), which may consist of an arrangement of cavities corresponding to the MEMS components and/or electronic chips, may be oriented suitably (or fittingly) to the first stripe and is attached to the latter. This procedure may be effected by using bond material (for example, an adhesive, epoxy material, etc.). The bond material may be attached on the substrate stripe (i.e. the base master structure) in a suitable manner, for example, by means of dispersing, stamping, printing, etc. Alternatively or in addition, it may be possible to attach such bond material using the mentioned or other methods on the cover master structure. After both stripes or master structures have been connected with one another, the individual packages may be singularized.

In order to possibly allow a pressure wave or a sound wave to reach the MEMS component, one via hole or plural via holes may be provided in one or both of the master structures. This architecture may enable a bottom access of the pressure or sound waves, if the via hole is arranged between solder pads of the base master structure, or may be a port on the top, if the via hole is provided at the cover master structure. Preferably, the via hole may be provided to be non-flush with a membrane of the MEMS component, in order to possibly exclude a damage of the same by the influence of a mechanical load through the via hole. A package having a via hole on the top may have a smaller footprint, whereas a via hole at the bottom may show a higher sensitivity due to its higher back volume. The port must not be in a straight line, but may have a desired and thus also more complex shape, and may be guided, for example, through a PCB.

At least one of the semiconductor chips and/or at least passive component may also be embedded in one of the master structures, in order to possibly reduce the package dimensions and to possibly improve the electrical performance.

If a hermetic connection is manufactured between the MEMS component (in particular the sensor element of the same) and the via hole (in order to make impossible an external access, which might damage other parts of the system), the assembly and/or the package may be realized with fluid sensors.

When providing membrane-based MEMS components, it may be advantageous to enclose them as far as possible, in order to possibly mechanically protect the movable element, however, without decoupling the membranes from the air connection, via which they may sense a sensor signal. This may for example be achieved by a PCB as a cover master structure or by a metal cap.

According to an exemplary embodiment example, the manufacturing effort may be kept low, in particular if two PCBs are used as master structures. It may thus be possible to reduce the risk of a misalignment (which may lead to a reduction of the yield) and to increase the production speed.

It may be possible to functionalize the cover master structure and/or to structure it, for example to enable passively filtering. This may be an additional advantage to the simplified mounting and the lower NRE (non-recurring engineering) costs.

When providing a via hole in one of the master structures, a (preferably smaller) via hole may also be provided in the respective other master structure, in order to possibly accomplish a pressure balance.

A cavity provided around an MEMS component (for example for the example of a loudspeaker as MEMS component) may ideally be as close as possible to a shape of a hemisphere, in order to possibly disable sound reflections, which would negatively influence the performance of the package. Such a hemispherical cavity may be achieved, for example, by drilling or milling using a spherical bit.

It may also be possible, in addition to the electronic chip, to integrate one or plural passive components (for example, an ohmic resistance, a capacitor or an electrically conductive and thermally conductive block, for example a copper block) in the base structure.

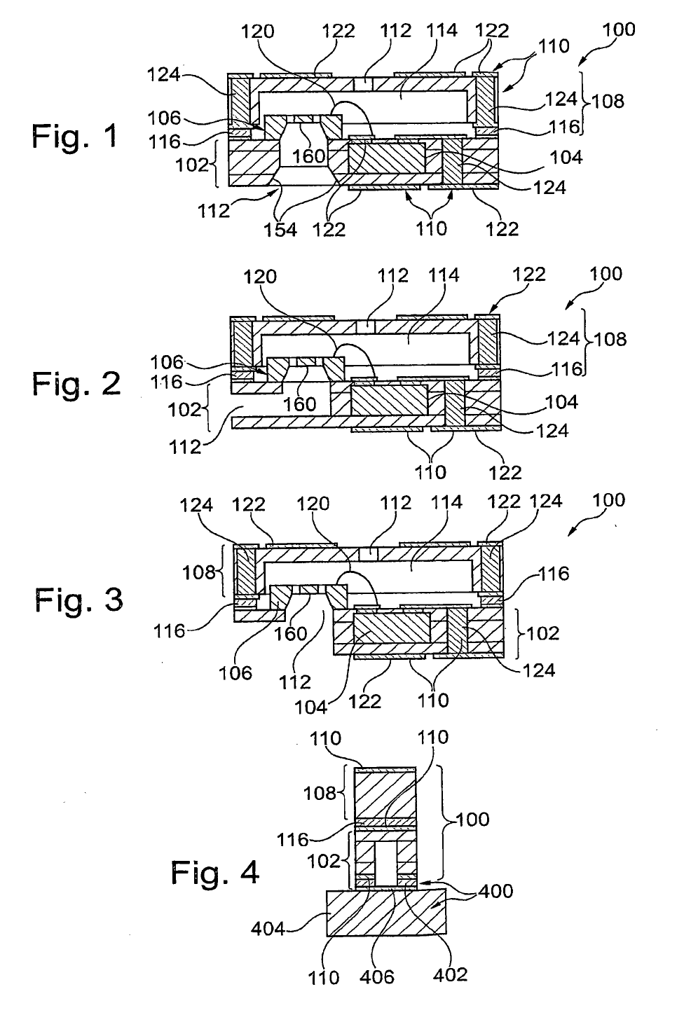

FIG. 1 shows a cross-sectional view of a package 100 according to an exemplary embodiment example of the invention. The package 100 according to FIG. 1 may be configured as a loudspeaker.

The package 100 may comprise a base structure 102 in the form of a section and/or a portion of a printed circuit board, which may comprise FR4 as an electrically isolating material and may comprise copper structures provided partially in and partially on the electrically isolating material as an electrically conductive contact structure 110. The electrically conductive contact structure 110 may have both structured electrically conductive layers (see reference numeral 122) and also vertical through-connections, so-called vias (see reference numeral 124). An electronic chip 104, which may be configured as an ASIC, may be embedded in the base structure 102, but could alternatively also be surface-mounted to the base structure 102, and may serve as a controller IC. According to FIG. 1, the surfaces at the side (or lateral surfaces) and also the mutually opposite upper and lower main surfaces of the electronic chip 102 may be covered with material of the base structure 102.

A microelectromechanical system (MEMS) component 106 may be surface-mounted on the base structure 102 and may be coupled electrically conductively to the electronic chip 104 by means of the electrically conductive contact structure 110 and by means of a bonding wire 120, such that electrical signals can propagate between the electronic chip 104 and the MEMS component 106. In other embodiment examples, in which the electronic chip 104 may be mounted in a flip chip configuration, the bond wire 120 may be omitted and the electrical coupling of the flip chip mounted electronic chip 104 may be effected by means of solder balls.

A cap-type cover structure 108, which may be formed as a section or a portion of a further printed circuit board (PCB) in the embodiment example, may be mounted on the base structure 102, so as to possibly cover the MEMS component 106. This means, that also the cover structure 108 may comprise dielectric material (in particular FR4) and an electrically conductive contact structure 110 made of copper, in correspondence to the base structure 102. Alternatively, the cover structure 108 may also be formed, for example, as a metal cap or as a casting compound.

In the present case, the electronic chip 104 may be configured for controlling the MEMS component 106. This means, that the electronic chip 104 of the MEMS component 106, which may be formed as a loudspeaker, transmits electrical signals that may be indicative for an audio content to be reproduced, on the basis of which a swingable membrane 160 of the MEMS component 106 may be excited to [perform] oscillations (or swings). Thus, acoustical waves may be generated, which can be emitted into the environment through one of via holes 112 provided in an outer casing of the package 100.

Both the base structure 102 and also the cover structure 108 may have a respective via hole 112 for providing an air connection between the MEMS component 106 and an environment of the package 100, through which [via hole] a sound connection may be formed between an interior and an outside of the package 100. An outer region of the via hole 112, which may be formed in the base structure 102, may be provided with a chamfer section 154, in order to possibly improve the propagation properties of the acoustical waves between an interior and an outside of the package 100.

The MEMS component 106 may be arranged distance-afflicted in a cavity 114 and/or in an opening of the cover structure 108 (which may be produced, for example, by means of etching the PCB structure), which [cavity or opening] may be confined between the base structure 102 and the cover structure 108. In this way, it may be ensured that the membrane 160 of the MEMS component 106 may be freely swingable (or capable to oscillate).

The package 100 may have electrically conductive bond material 116 (for example metallic solder material) at a mounting site between the base structure 102 and the cover structure 108. Since this electrically conductive bond material 116 may contact the electrically conductive contact structures 110 of the base structure 102 and of the cover structure 108 on both sides (i.e. on the top side and on the bottom side) and may connect them with one another, an electrically conductive connection may be established also between the base structure 102 and the cover structure 108 by means of the bond material 116.

In FIG. 1, a package 100 can be recognized, in which the MEMS component 106 may be formed as an MEMS loudspeaker. In the case of an embodiment as a MEMS loudspeaker, the electronic chip 104 may provide control signals to the loudspeaker in the form of the MEMS component 106 via the electrically conductive contact structure 110, which control signals may be converted to sound by a piezoelectric membrane 160 of the MEMS component 106. This sound may exit, through one of the via holes 110, into an environment, where it may be audible.

A similar configuration may also serve as an MEMS microphone. In the case of an embodiment as a microphone, acoustical waves would propagate from the environment through one or both of the via holes 112 into the cavity 114 and may excite the piezoelectric membrane 160 to [perform] oscillations. Thus, corresponding electrical signals would be produced at the MEMS component 106, which [signals] could be transmitted to the electronic chip 104 and could thus be further processed.

By the burying of the electronic chip 104 in the base structure 102, a vertical arrangement of the electronic chip and the MEMS structure 106 may be enabled, which may lead to a compact configuration in the height direction. In addition, a low constructional height may be achieved also by the provision of plate-shaped PCBs as a basis for the base structure 102 and the cover structure 108. By arranging the electronic chip 104 and the MEMS component 106 approximately vertically on top of one another, a compact configuration may be enabled also in a lateral direction.

At a bottom side of the package 100 according to FIG. 1, the latter can be mounted to a substrate, for example, to a printed circuit board (not shown).

FIG. 2 shows a cross-sectional view of a package 100 according to another exemplary embodiment example of the invention. The package 100 according to FIG. 2 may be configured as a balanced armature receiver.

The package 100 according to FIG. 2 may differ from the package 100 according to FIG. 1 in that according to FIG. 2, the larger one of the two via holes 112 (a so-called ventilation hole) may be arranged laterally (or at a side) and not at a bottom side of the base structure 102. In this way, a mounting of the bottom side of the package 100 at a substrate (not shown) may be possible without the air connection of the MEMS component 106 being impeded thereby. A ventilation air channel, which may be constituted by the lower via hole 112, may thus be oriented partially parallel to the membrane 160 of the MEMS component 106.

FIG. 3 shows a cross-sectional view of a package 100 according to another exemplary embodiment example of the invention. The package 100 according to FIG. 3 may be configured partially as a balanced armature receiver.

The package 100 according to FIG. 3 may differ from the packages 100 according to FIG. 1 and/or FIG. 2 in that according to FIG. 3 there may be provided a step-shaped bottom side. The lower via hole 112 may be arranged in one region of the step, while another region of the step may be free for mounting the package 100 to a substrate.

FIG. 4 shows a cross-sectional view of the package 100, and how this is mounted to a substrate 400 by means of bond material 402. In the embodiment example shown, the substrate 400 may be embodied as a printed circuit board (PCB) and may have an electrically isolating core 404 and an electrically conductive wiring 406, by means of which the substrate 400 may be electrically coupled with the package 100. Thus, FIG. 4 shows a receiver on a PCB.

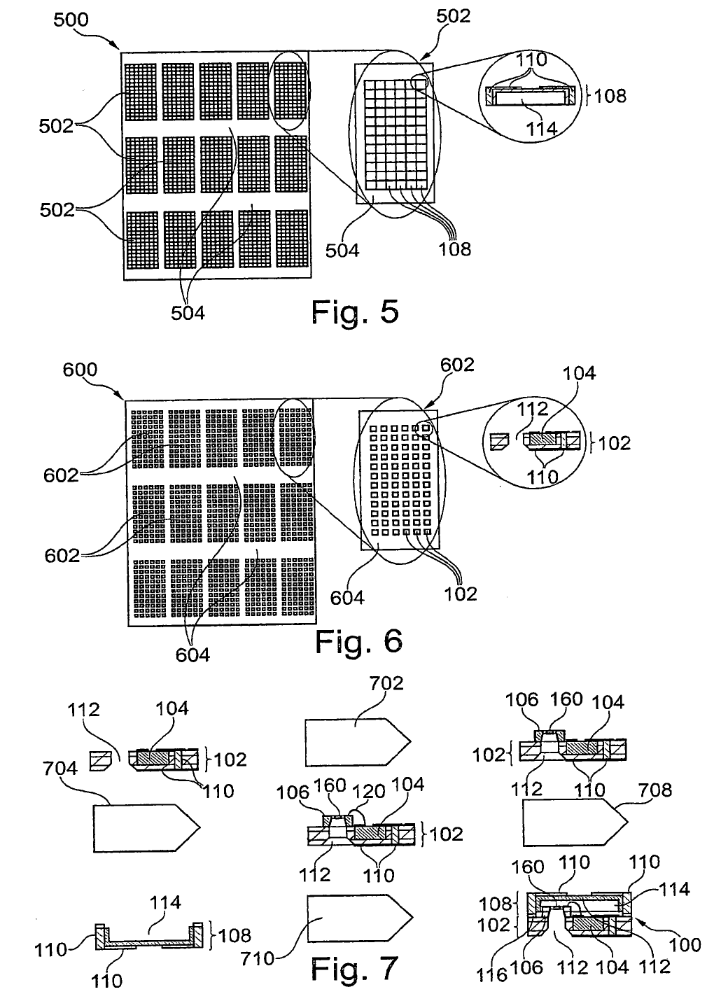

FIG. 5 shows a cover master structure 500 according to an exemplary embodiment example of the invention.

The cover master structure 500 may be formed on a printed circuit board. A plurality of active cover sections 502 may be arranged in the form (or shape) of a matrix, i.e. in rows and columns, on the shown main surface of the cover master structure 500. Inactive areas 504 may be provided between the active cover sections 502. FIG. 5 shows furthermore that each one of the active cover sections 502 may have in turn a plurality of cover structures 108 arranged in rows and columns. These may be embodied such as it has been described with references to FIG. 1 to FIG. 3. The cavities 104, which may be provided to this end, may be produced by means of etching, for example. In summary, FIG. 5 shows that the cover master structure 500 shown there may be well suitable for a batch-wise production of packages 100 according to exemplary embodiment examples.

FIG. 6 shows a base master structure 600 according to an exemplary embodiment example of the invention.

In the base master structure 600, package formation sections 602 may be arranged in rows and columns, and may thus be separated by inactive sections 604. Furthermore in FIG. 6, one of the package formation sections 602 is shown in an enlarged representation, in which it can be seen, that a plurality of base structures 102 may be formed in rows and columns, hence in the form of a matrix. These may be formed such as it has been shown according to FIGS. 1 to 3.

In order to manufacture a plurality of packages 100 in a batch-wise manner, the cover master structure 500 according to FIG. 5 can be attached to the base master structure 600 according to FIG. 6 by means of an adhesive compound (not shown) and another bond material. Subsequently, a singularization of the thus obtained assembly (see reference numeral 1100 in FIG. 11) may be performed, in order to possibly separate the individual packages 100 from one another.

FIG. 7 shows a schematic view of processes during a method for manufacturing packages 100 according to an exemplary embodiment example of the invention.

As is illustrated by means of the reference numeral 702, the MEMS component 106 may be attached to a top side of the base structure 102 by means of die bonding, such that a mechanical attachment may be enabled simultaneously, and such that an electrical contacting to the electronic chip 104, which may be provided buried in the base structure 102, may be prepared. Such as is shown by means of the reference numeral 704, a bond wire 120 can be attached to the MEMS component 106 by means of wire bonding, in order to possibly electrically couple the latter with the electronic chip 104. As is shown by means of the reference numeral 708, a cavity 114 may be formed in the cover structures 108. Subsequently, a batch-wise connection between a base master structure 600 and a cover master structure 500, or a connection between a base structure 102 that may have been singularized already and a cover structure 108 that may have been singularized already may be performed, in order to possibly produce the package 100 shown in FIG. 7. Subsequently, a singularizing to individual packages may be performed in the case of a batch-wise processing.

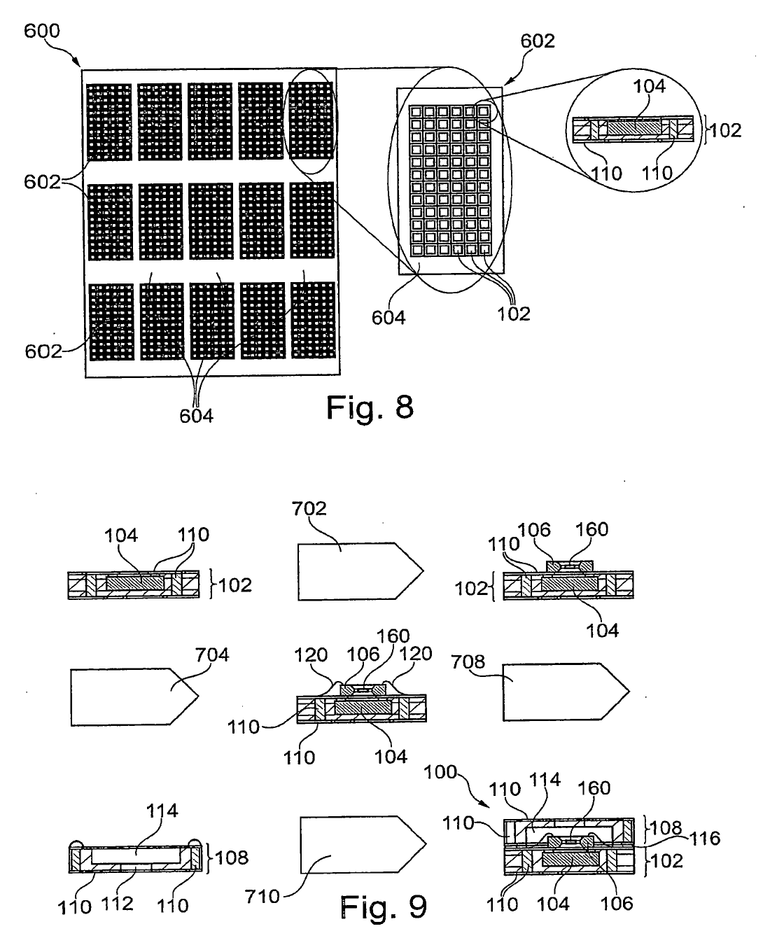

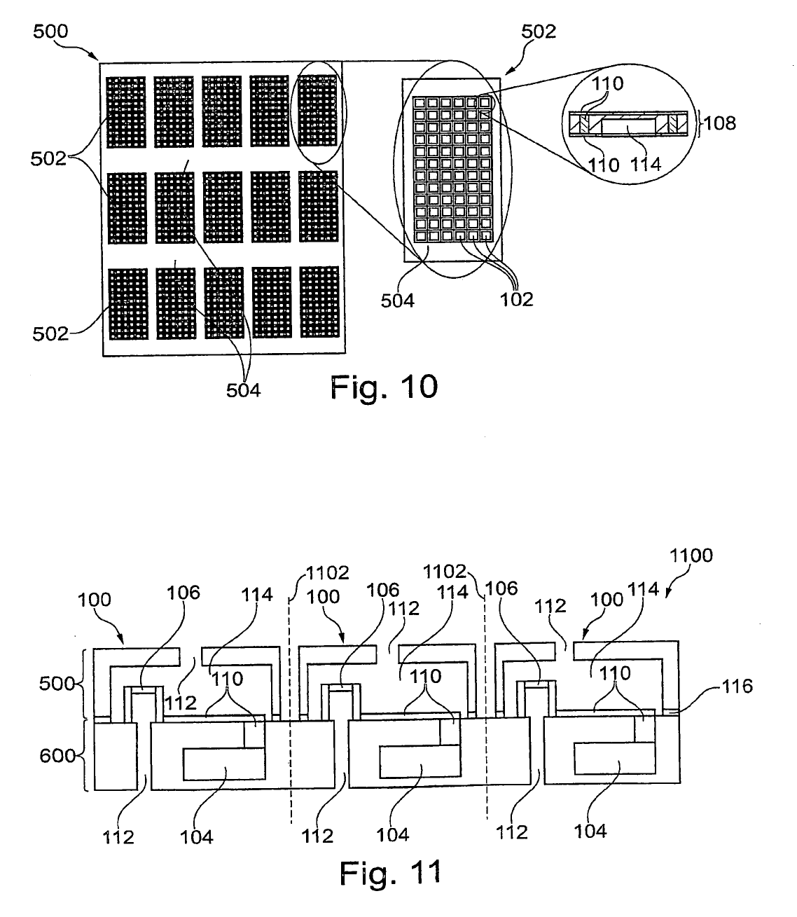

FIG. 8, FIG. 9 and FIG. 10 show a very similar procedure as in FIG. 5 to FIG. 7, wherein FIG. 8 may correspond to FIG. 6, FIG. 9 may correspond to FIG. 7 and FIG. 10 may correspond to FIG. 5. The difference between the embodiment examples of FIG. 8 to FIG. 10 in comparison with the embodiment examples of FIG. 5 to FIG. 7 may be that different base structures 102 and different cover structures 108 may be implemented. According to FIG. 8 to FIG. 10, a respective MEMS component 106 may be arranged directly above the electronic chip 104, instead of being arranged laterally shifted as according to FIG. 5 to FIG. 7.

FIG. 11 shows a cross-sectional view of an assembly 1100 according to an exemplary embodiment example of the invention.

The assembly 1100 may comprise a base master structure 600; a plurality of electronic chips 104, which may be embedded in the base master structure 600; a plurality of MEMS components 106, which may be arranged on the base master structure 600; and a cover master structure 500, which may be mounted to and/or on the base master structure 600, and which may cover the MEMS components 106. Thus, individual cavities 114 may be defined for each one of the MEMS components 106 between a respective section of the base master structure 600 and a respective section of the cover master structure 500.

In the assembly 1100 shown in FIG. 11, a singularization into packages 100 may be effected by separating the individual packages 100 from one another along separation lines or cutting lines 1102 (for example by means of sawing, laser cutting or etching).

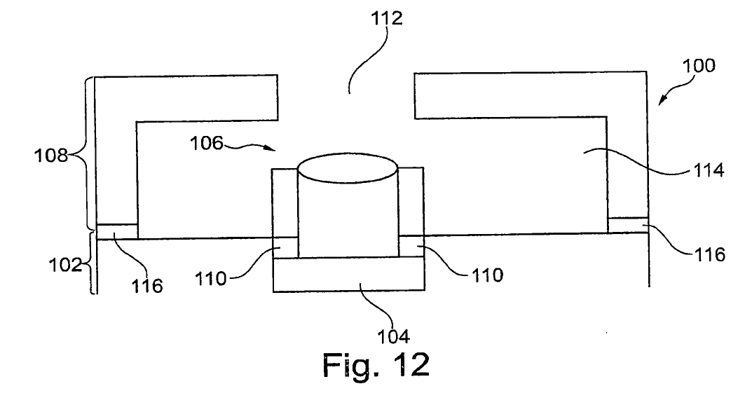

FIG. 12 shows a cross-sectional view of a package 100 according to another exemplary embodiment example of the invention.

According to FIG. 12, the electronic chip 104 may be formed as a CCD (charge coupled device) and may detect electromagnetic radiation. The electronic chip 104 of the CCD type may be embedded in the base structure 102, wherein an upper surface of the CCD chip may be exposed with respect to the base structure 102, in order to possibly be sensitive for electromagnetic radiation. The electronic chip 104 may cooperate with an electrically movable lens by means of an electrically conductive contact structure 110, wherein the lens as an MEMS component 106 may be arranged above the electronic chip 104, in order to possibly serve as an adjustable optical element for influencing the electromagnetic radiation that may be detected by means of the CCD. In the embodiment example according to FIG. 12, at least a section of the cover structure 108 above the MEMS component 106 and the electronic chip 104 may be optically transparent, or the cover structure 108 should have a via hole 112, which may allow light to propagate into the cavity 114.

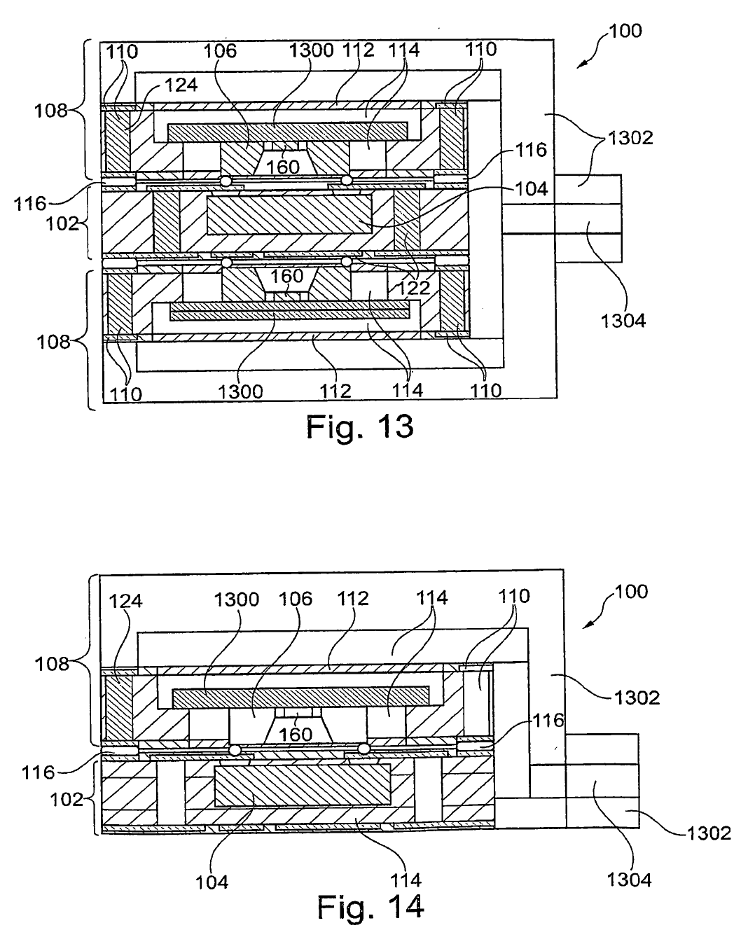

FIG. 13 and FIG. 14 show cross-sectional views of packages 100 according to other exemplary embodiment examples of the invention.

The package 100 shown in FIG. 13 may be formed as a balanced armature receiver (BAR) having a double-sided configuration. This means that a base structure 102 having an embedded electronic component 104 may be populated (or fitted with components) on each of its two opposing main surfaces with a respective MEMS component 106, which in turn may be covered by means of a respective cover structure 108. In addition, a membrane 1300 may cover an exposed surface of the respective MEMS component 106. The membrane 1300 may be manufactured, for example, from silicon, or from another polymer material. In this way, a compact design (or configuration) can be combined with a high level of functionality. FIG. 13 shows furthermore a housing 1302 (for example made of metal or of plastics), which may serve as a guide for sound waves, and which may have a sound access opening 1304.

The package 100 shown in FIG. 14 may be formed as a balanced armature receiver (BAR) having a single-sided configuration. This means that a base structure 102 having an embedded electronic component 104 may be populated with an MEMS component 106 only on one of its two opposing main surfaces, which MEMS component 106 may in turn be covered by means of a membrane 1300 and may be enclosed by a cover structure 108. According to FIG. 14 too, there may be provided a housing 1302, which may be configured according to FIG. 13.

As a supplement, it is to be noted that “comprising” or “having” may not exclude other elements or steps, and that “a” or “an” may not exclude a plurality. Furthermore, it should be noted that features or steps, which have been described with reference to one of the embodiment examples above, may be used also in combination with other features or steps of other embodiment examples described above. Reference numerals in the claims may not to be construed as limitations.

1. A package comprising:
a base structure, which has an electrically isolating material and/or an electrically conductive contact structure;
an electronic component, which is embedded in the base structure or is arranged on the base structure;
a microelectromechanical system (MEMS) component; and
a cover structure, which is mounted on the base structure for at least partially covering the MEMS component.

2. The package according to claim 1, wherein the base structure is configured as a conductor board or as a section thereof.

3. The package according to claim 1, wherein the cover structure is selected from a group, which consists of: a casting compound, a die cast component, a metal cap, and a further electrically isolating material having a further electrically conductive contact structure, a conductor board, a printed circuit board, or a section thereof.

4. The package according to claim 1, wherein the electrically isolating material is selected from a group, which consists of: resin, bismaleimide-triazine resin, glass fibres, prepreg material, polyimide, a liquid crystal polymer, epoxy-based build-up film, and FR4 material.

5. The package according to claim 1, wherein the electronic component is configured for functionally cooperating with the MEMS component.

6. The package according to claim 1, wherein the MEMS component is formed as one of the group, which consists of: a sensor, an actuator, a loudspeaker, a balanced armature receiver, a microphone, an autofocus component, a two-dimensional scanner, a haptic actuator, a pressure sensor, a micropump, an adjustable lens, an adjustable wavelength-selective filter, and a fluid sensor.

7. The package according to claim 1, wherein the electronic component is a semiconductor integrated circuit.

8. The package according to claim 1, wherein at least a portion of surfaces at the side of the electronic component is covered with material of the base structure.

9. The package according to claim 1, wherein at least one of the group, which consists of: the base structure and the cover structure, has:
at least a via hole for providing a fluid connection between the MEMS component and an environment of the packaged, and/or
a surface structuring for influencing acoustic waves.

10. (canceled)

11. The package according to claim 1, wherein the MEMS component is arranged in a cavity, which is confined between the base structure and the cover structure.

12. The package according to claim 1, wherein the cover structure has at least one of the group, which consists of: an EMI protection device, an ESD protection device, at least one solder pad, and a feature for adapting acoustic waves.

13. The package according to claim 1, further having bonding material at a mounting site between the base structure and the cover structure.

14. The package according to claim 13, wherein the bonding material is configured for providing both a mechanical connection and an electrical coupling between the base structure and the cover structure.

15. The package according to claim 1, wherein at least a portion of the electrically conductive contact structure is configured for electrically coupling the electronic component with the MEMS component.

16. The package according to claim 1, wherein the MEMS component is mounted on the base structure and/or on the cover structure.

17. A method for manufacturing packages, the method comprising:
embedding an electronic component in, or arranging the electronic component on a base structure, which has an electrically isolating material and/or an electrically conductive contact structure;
mounting a microelectromechanical system (MEMS) component at the base structure; and
at least partially covering the MEMS component with a cover structure, which is mounted at the base structure.

18. The method according to claim 17, the method further comprising:
embedding at least one further electronic component in, or arranging the at least one further electronic component on, a base master structure, wherein the base structure forms a portion of the base master structure;
mounting at least one further MEMS component at the base master structure;
at least partially covering the at least one further MEMS component with a cover master structure, which is mounted at the base master structure, wherein the cover structure forms a portion of the cover master structure.

19. The method according to claim 17, further comprising:
singularizing of the arrangement of the base master structure having the electronic components and the mounted MEMS components and the cover master structure, in order to thereby obtain a plurality of packages, each of which comprises a base structure, an electronic component, a MEMS component and a cover structure.

20. The method according to claim 17, wherein the electronic components and the MEMS components are distributed two-dimensionally across the base master structure and the cover master structure.

21. An assembly, comprising:
a base master structure, which has an electrically isolating material and/or an electrically conductive contact structure;
a plurality of electronic components, which are embedded in the base master structure, or are arranged on the base master structure;
a plurality of MEMS components at the base master structure;
a cover master structure, which is mounted at the base master structure and at least partially covers the MEMS components, in order to thus define individual cavities for each one of the MEMS components between a respective section of the base master structure and a respective section of the cover master structure.
